(19) United States
(12) Patent Application Publication
(10) Pub. No.: US 2021/0206906 A1
(43) Pub. Date: Jul. 8, 2021

(54) RESIN COMPOSITION, RESIN MEMBER, RESIN SHEET, B-STAGE SHEET, C-STAGE SHEET, METAL FOIL WITH RESIN, METAL SUBSTRATE, AND POWER SEMICONDUCTOR DEVICE

(71) Applicant: Showa Denko Materials Co., Ltd., Chiyoda-ku, Tokyo (JP)

(72) Inventors: Kazuya KIGUCHI, Chiyoda-ku, Tokyo (JP); Tomoo NISHIYAMA, Chiyoda-ku, Tokyo (JP); Hidetoshi INOUE, Chiyoda-ku, Tokyo (JP); Yoshihiro AMANO, Chiyoda-ku, Tokyo (JP); Daisuke FUJIMOTO, Chiyoda-ku, Tokyo (JP)

(21) Appl. No.: 17/059,253

(22) PCT Filed: May 31, 2018
(86) PCT No.: PCT/JP2018/021058

§ 371 Date: Nov. 26, 2020

(51) Int. Cl. C08G 59/24; B32B 15/092; C08L 63/00; H01L 23/373

(52) U.S. Cl. CPC C08G 59/245; H01L 23/3735; C08L 63/00; B32B 15/092

(57) ABSTRACT

A resin composition having, in a cured state, a thermal conductivity of 5 W/(m·K) or more and a storage elastic modulus of 8 GPa or less.

### TECHNICAL FIELD

The invention relates to a resin composition, a resin member, a resin sheet, a B-state sheet, a C-stage sheet, a metal foil with resin, a metal substrate, and a power semiconductor device.

### BACKGROUND ART

In electronic component devices, a member including resin (resin member) is used for the purpose of electrical insulation and the like. Recently, the dissipation of heat generated in electronic component devices has become an increasingly important issue as devices are reduced in size and the power thereof increases. However, while resin is highly insulating, it has inferior heat conductivity. Therefore, a technique of imparting favorable heat conductivity to resin members has been developed (see, for example, Patent Document 1 and Patent Document 2).

### PRIOR ART DOCUMENT

### Patent Documents

[Patent Document 1] Japanese Patent No. 5431595

[Patent Document 2] Japanese Patent No. 4118691

### SUMMARY OF THE INVENTION

### Problem to be Solved by the Invention

In the invention described in Patent Document 1, the heat conductivity of a resin member is improved by using a resin composition in which a specific type of filler is added to an epoxy resin.

In the invention described in Patent Document 2, the heat conductivity of a resin member is improved by using a resin composition including an epoxy resin having a mesogenic structure in its molecule as an insulating material.

Meanwhile, in line with the recent dissemination of low-profile electronic component devices, the occurrence of warpage of the devices due to a difference in thermal expansion rate between a resin member and a member that is in contact with the resin member has become more common, and is cause for concern in terms of impairing connection reliability owing to exfoliation or cracking of the resin member. As such, development of a material that can form a resin member that achieves favorable connection reliability while maintaining sufficient thermal conductivity, is desired.

In view of the foregoing, an embodiment of the invention aims to provide a resin composition that can form a resin member that achieves favorable connection reliability while maintaining sufficient thermal conductivity; and a resin member, a resin sheet, a B-stage sheet, a C-stage sheet, a metal foil with resin, a metal substrate and a power semiconductor device, which are obtained using the resin composition.

### Means for Solving the Problem

The means for solving the problem include the following embodiments.

<1> A resin composition having, in a cured state, a thermal conductivity of 5 W/(m·K) or more and a storage elastic modulus of 8 GPa or less.

<2> The resin composition according to <1>, comprising a thermosetting resin.

<3> The resin composition according to <1> or <2>, comprising an epoxy resin having a non-cyclic alkylene group of not less than 4 carbon atoms.

<4> The resin composition according to any one of <1> to <3>, comprising a phenol resin having an allyl group that is directly bonded to a carbon atom in an aromatic ring, or having an alkyl group of not less than 4 carbon atoms that is directly bonded to a carbon atom in an aromatic ring.

<5> A resin composition, comprising an epoxy resin having a non-cyclic alkylene group of not less than 4 carbon atoms.

<6> A resin member, comprising a cured product of the resin composition according to any one of <1> to <5>.

<7> A resin sheet, comprising the resin composition according to any one of <1> to <5>.

<8> A B-stage sheet, comprising a semi-cured product of the resin sheet according to <7>.

<9> A C-stage sheet, comprising a cured product of the resin sheet according to <7>.

<10> A metal foil with resin, comprising a metal foil and a semi-cured product of the resin sheet according to <7>, which is disposed on the metal foil.

<11> A metal substrate, comprising a metal support, a cured product of the resin sheet according to <7>, which is disposed on the metal support, and a metal foil that is disposed on the cured product.

<12> A power semiconductor device, comprising a semiconductor module in which a metal plate, a solder layer and a semiconductor chip are layered in this order; a heat dissipation member; and a cured product of the resin sheet according to <7>, which is disposed between the metal plate of the semiconductor module and the heat dissipation member.

### Effect of the Invention

According to an embodiment of the invention, it is possible to provide a resin composition that can form a resin member that achieves favorable connection reliability while maintaining sufficient thermal conductivity; and a resin member, a resin sheet, a B-stage sheet, a C-stage sheet, a metal foil with resin, a metal substrate and a power semiconductor device, which are obtained using the resin composition.

### BRIEF EXPLANATION OF THE DRAWINGS

FIG. 1 is a schematic sectional view showing an exemplary configuration of a power semiconductor device according to the disclosure.

FIG. 2 is a schematic sectional view showing another exemplary configuration of a power semiconductor device according to the disclosure.

FIG. 3 is a schematic sectional view showing an exemplary configuration of a package used for the evaluation of connection reliability.

### EMBODIMENTS FOR IMPLEMENTING THE INVENTION

Embodiments according to the disclosure will now be described in detail. However, the invention is in no way limited to the following embodiments. In the following embodiments, constituent elements (including element steps and the like) of the embodiments are not essential, unless otherwise specified. Likewise, numerical values and ranges thereof are not intended to restrict the invention.

In the present disclosure, the definition of the term “step” includes not only an independent step which is distinguishable from another step, but also a step which is not clearly distinguishable from another step, as long as the purpose of the step is achieved.

In the present disclosure, any numerical range described using the expression “to” represents a range in which numerical values described before and after the “to” are included in the range as a minimum value and a maximum value, respectively.

In a numerical range described in stages, in the present disclosure, an upper limit value or a lower limit value described in one numerical range may be replaced with an upper limit value or a lower limit value in another numerical range described in stages. Further, in a numerical range described in the present disclosure, the upper limit value or the lower limit value in the numerical range may be replaced with a value shown in the Examples.

In the present disclosure, each component may include plural kinds of substances corresponding to the component. In a case in which plural kinds of substances corresponding to each component are present in a composition, the content ratio or content of each component refers to the total content ratio or content of the plural kinds of substances present in the composition, unless otherwise specified.

In the present disclosure, particles corresponding to each component may include plural kinds of particles. In a case in which plural kinds of particles corresponding to each component are present in a composition, the particle size of each component refers to the value of the particle size of a mixture of the plural kinds of particles present in the composition, unless otherwise specified.

In the present disclosure, when the region at which a layer is present is observed, the term “layer” refers not only to a case in which the layer is formed on the entire region but also a case in which the layer is formed at a portion of the region.

In the present disclosure, the term “laminate” refers to a state in which a layer is disposed on another layer, and the layers may be bonded or detachable from each other.

In the present disclosure, when the embodiments are explained by referring to a drawing, the configuration of the embodiments are not limited to those illustrated in the drawing. Further, the members in the drawing are illustrated with conceptual sizes, and the relative relationship thereof is not limited thereto.

### Resin Composition (First Embodiment)

The resin composition according to the first embodiment is a resin composition having, in a cured state, a thermal conductivity of 5 W/(m·K) or more and a storage elastic modulus of 8 GPa or less.

The inventors have found that a favorable connection reliability of a resin member can be maintained by appropriately adjusting the storage elastic modulus of the resin member, and have arrived at the resin composition according to the disclosure. Specifically, a resin member, which is a cured product of the resin composition that has, in a cured state, a storage elastic modulus of 8 GPa or less, exhibits favorable connection reliability. Further, the resin composition according to the disclosure has, in a cured state, a thermal conductivity of 5 W/(m·K) or more. Therefore, a cured product of the resin composition exhibits favorable thermal conductivity.

The storage elastic modulus of the resin composition in a cured state is not particularly limited as long as it is 8 GPa or less. For example, the storage elastic modulus of the resin composition in a cured state is preferably 5 GPa or less, more preferably 2 GPa or less.

In the disclosure, the storage elastic modulus of the resin composition in a cured state is measured by a method described in the Examples.

The thermal conductivity of the resin composition in a cured state is not particularly limited as long as it is 5 W/(m·K) or more. For example, the thermal conductivity of the resin composition in a cured state is preferably 8 W/(m·K) or more, more preferably 10 W/(m·K) or more.

In the disclosure, the storage elastic modulus of the resin composition in a cured state is measured by a method described in the Examples.

(Resin)

The resin composition includes a resin. The type of the resin is not particularly limited, and examples thereof include thermosetting resins and thermoplastic resins. The resin may be a combination of a thermosetting resin and a curing agent.

From the viewpoint of insulating properties, heat resistance and the like, the resin composition preferably includes a thermosetting resin. Examples of the thermosetting resin include epoxy resin, phenol resin, urea resin, melamine resin, urethane resin, silicone resin and unsaturated polyester resin. In the disclosure, a resin that exhibits both of a property that is specific to a thermoplastic resin and a property that is specific to a thermosetting resin is regarded as a thermosetting resin. The resin composition may include a single kind of a resin or may include two or more kinds.

Among the thermosetting reins, from the viewpoint of electrical insulating properties, heat resistance and the like, the resin composition preferably includes an epoxy resin.

The type of the epoxy resin is not particularly limited, and may be selected depending on the desired characteristics of the resin composition, and the like.

Specific examples of the epoxy resin include novolac epoxy resin (such as a phenol novolac epoxy resin or an ortho-cresol novolac epoxy resin) which is obtained by epoxidizing a novolac resin obtained by condensation or co-condensation of at least one phenolic compound selected from the group consisting of phenol compounds such as phenol, cresol, xylenol, resorcinol, catechol, bisphenol A and bisphenol F, and naphthol compounds such as α-naphthol, β-naphthol and dihydroxynaphthalene, with an aliphatic aldehyde compound such as formaldehyde, acetaldehyde or propionaldehyde, in the presence of an acidic catalyst; triphenylmethane epoxy resin which is obtained by epoxidizing a triphenylmethane phenol resin obtained by condensation or co-condensation of the above-described phenolic compound with an aromatic aldehyde compound such as benzaldehyde or salicylaldehyde in the presence of an acidic catalyst; copolymerized epoxy resins which is obtained by epoxidizing a novolac resin obtained by co-condensation of any of the above-described phenol compound and the naphthol compound with an aldehyde compound in the presence of an acidic catalyst; diphenylmethane epoxy resin which is a diglycidyl ether of bisphenol A, bisphenol F or the like; biphenyl epoxy resin which is a diglycidyl ether of an alkyl-substituted or unsubstituted biphenol; stilbene epoxy resin which is a diglycidyl ether of a stilbene phenol compound; sulfur atom-containing epoxy resin which is a diglycidyl ether of bisphenol S or the like; epoxy resin which is a glycidyl ether of an alcohol such as butanediol, polyethylene glycol or polypropylene glycol; glycidyl ester epoxy resin which is a glycidyl ester of a polyvalent carboxylic acid compound such as phthalic acid, isophthalic acid or tetrahydrophthalic acid; glycidyl amine epoxy resin which is obtained by substituting an active hydrogen bound to a nitrogen atom of aniline, diaminodiphenylmethane, isocyanuric acid or the like, with a glycidyl group; dicyclopentadiene epoxy resin which is obtained by epoxidizing a co-condensed resin of dicyclopentadiene with a phenol compound; alicyclic epoxy resin which is obtained by epoxidizing an olefin bond in the molecule, such as vinylcyclohexene diepoxide, 3,4-epoxycyclohexylmethyl-3,4-epoxycyclohexane carboxylate or 2-(3,4-epoxy)cyclohexyl-5,5-spiro(3,4-epoxy)cyclohexane-m-dioxane; paraxylylene-modified epoxy resin which is a glycidyl ether of a paraxylylene-modified phenol resin; metaxylylene-modified epoxy resin which is a glycidyl ether of a metaxylylene-modified phenol resin; terpene-modified epoxy resin which is a glycidyl ether of a terpene-modified phenol resin; dicyclopentadiene-modified epoxy resin which is a glycidyl ether of a dicyclopentadiene-modified phenol resin; cyclopentadiene-modified epoxy resin which is a glycidyl ether of a cyclopentadiene-modified phenol resin; polycyclic aromatic ring-modified epoxy resin which is a glycidyl ether of a polycyclic aromatic ring-modified phenol resin; naphthalene epoxy resin which is a glycidyl ether of a naphthalene ring-containing phenol resin; halogenated phenol novolac epoxy resin; hydroquinone epoxy resin; trimethylolpropane epoxy resin; linear aliphatic epoxy resin which is obtained by oxidizing an olefin bond with a peracid such as peracetic acid; and aralkyl epoxy resin which is obtained by epoxidizing an aralkyl phenol resin such as a phenol aralkyl resin or a naphthol aralkyl resin. These epoxy resins may be used singly, or in combination of two or more kinds thereof.

The resin composition may include an epoxy resin having a non-cyclic alkylene group of not less than 4 carbon atoms (hereinafter, also referred to as a specific epoxy resin).

The inventors have found that by including a specific epoxy resin in the resin composition, it is possible to reduce the storage elastic modulus of a cured product thereof, while maintaining favorable thermal conductivity. The reason for this has not been clear, but one reason is considered to be a relatively flexible molecular structure of the specific epoxy resin having a non-cyclic alkylene group of not less than 4 carbon atoms. Another reason is considered to be that the non-cyclic alkylene group of not less than 4 carbon atoms functions to increase the degree of molecular orientation in a cured product of the resin composition, thereby maintaining the favorable thermal conductivity.

The non-cyclic alkylene group of not less than 4 carbon atoms of the specific epoxy resin may have a branch or a substituent. In that case, the number of carbon atoms included in the branch or the substituent is not included in the “carbon atoms” of the non-cyclic alkylene group.

From the viewpoint of achieving a sufficient effect of reducing the storage elastic modulus while maintaining the thermal conductivity, the non-cyclic alkylene group of not less than 4 carbon atoms preferably has no branch or substituent.

The carbon number of the non-cyclic alkylene group of not less than 4 carbon atoms of the specific epoxy resin is not particularly limited as long as it is not less than 4. For example, the carbon number may be from 4 to 8. The number of the non-cyclic alkylene group of not less than 4 carbon atoms included in the specific epoxy resin is not particularly limited. For example, the number of the non-cyclic alkylene group of not less than 4 carbon atoms included in the specific epoxy resin may be from 1 to 5, or from 2 to 4.

The number of the epoxy group of the specific epoxy resin is not particularly limited. For example, the specific epoxy resin preferably has two or more epoxy groups in one molecule, more preferably two epoxy groups in one molecule.

In an embodiment, the specific epoxy resin may be an epoxy resin represented by the following Formula (1) or Formula (2).

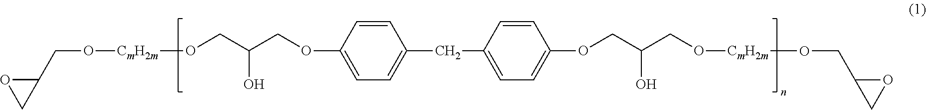

In Formula (1), each of m independently represents an integer of from 4 to 8, and n represents an integer of from 1 to 30.

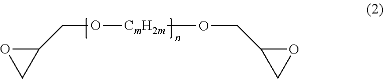

In Formula (2), each of m independently represents an integer of from 4 to 8, and n represents an integer of from 1 to 30.

From the viewpoint of reducing the storage elastic modulus by keeping the crosslinking density of a cured product low, the weight average molecular weight (Mw) of the specific epoxy resin is preferably 600 or more, more preferably 700 or more, further preferably 800 or more.

The number average molecular weight (Mn) of the specific epoxy resin is preferably 50 or more, more preferably 100 or more, further preferably 150 or more.

From the viewpoint of achieving a sufficient curability, the weight average molecular weight (Mw) of the specific epoxy resin is preferably 20000 or less, more preferably 15000 or less, further preferably 10000 or less.

The number average molecular weight (Mn) of the specific epoxy resin is preferably 1000 or less, more preferably 800 or less, further preferably 500 or less.

In the disclosure, the weight average molecular weight and the number average molecular weight of the specific epoxy resin are the values measured by gel permeation chromatography (GPC). The measurement of Mw and Mn by GPC is performed using G2000HXL and 3000HXL (Tosoh Corporation) as the GPC columns, tetrahydrofuran as the mobile phase, at a sample concentration of 0.2% by mass and a flow rate of 1.0 mL/min. A calibration curve is obtained using a polystyrene standard sample, and the Mw and the Mn are calculated as the polystyrene equivalent values.

The epoxy equivalent of the specific epoxy resin is preferably from 300 g/eq to 2000 g/eq, more preferably from 350 g/eq to 1700 g/eq, further preferably from 350 g/eq to 1500 g/eq.

The epoxy equivalent of the specific epoxy resin is regarded as a value measured by perchloric acid titration.

When the resin composition includes a specific epoxy resin, the resin composition may include only a specific epoxy resin as the epoxy resin, or may include a specific epoxy resin and an epoxy resin that is not a specific epoxy resin as the epoxy resin.

When the resin composition includes a specific epoxy resin and an epoxy resin that is not a specific epoxy resin as the epoxy resin, the proportion of the specific epoxy resin in the total epoxy resin is preferably 50% by mass or more, more preferably 70% by mass or more, further preferably 90% by mass or more.

The resin composition may include a curing agent. The type of the curing agent is not particularly limited, and may be selected depending on the desired properties of the resin composition, and the like.

Examples of the curing agent include a phenol curing agent, an amine curing agent, an acid anhydride curing agent, a polymercaptane curing agent, a polyaminoamide curing agent, an isocyanate curing agent, and a block isocyanate curing agent. Among these, a phenol curing agent and an amine curing agent are preferred. The resin composition may include a single kind of a curing agent, or two or more kinds thereof.

Specific examples of the phenol curing agent include a monofunctional phenol compound such as phenol, o-cresol, m-cresol and p-cresol, a difunctional phenol compound such as catechol, resorcinol and hydroquinone, a trifunctional phenol compound such as 1,2,3-trihydroxybenzene, 1,2,4-trihydroxybenzene, and 1,3,5-trihydroxybenzene, and a phenol resin obtained by linking the phenol compound with a methyelene group or the like (novolac).

Specific examples of the phenol resin include a phenol resin obtained by forming a novolac from a single kind of phenol compound, such as a phenol novolac resin, a cresol novolac resin, a catechol novolac resin, a resorcinol novolac resin and a hydroquinone novolac resin; and a phenol resin obtained by forming a novolac from two or more kinds of phenol compounds, such as a catechol-resorcinol novolac resin and a resorcinol-hydroquinone novolac resin.

From the viewpoint of the curability, the amine curing agent is preferably a compound having two or more functional groups (active hydrogens). From the viewpoint of the thermal conductivity, the amine curing agent is preferably a compound having a rigid structure such as an aromatic ring.

Specific examples of the difunctional amine curing agent include 4,4′-diaminodiphenylmethane, 4,4′-diaminodiphenylether, 4,4′-diaminodiphenylsulfone, 4,4′-diamino-3,3′-dimethoxybiphenyl, 4,4′-diaminophenylbenzoate, 1,5-diaminonaphthalene, 1,3-diaminonaphthalene, 1,4-diaminonaphthalene, 1,8-diaminonaphthalene, trimethylene-bis-4-aminobenzoate, poly-1,4-butanediol-bis-4-aminobenzoic acid, o-phenylenediamine, m-phenylenediamine, and p-phenylenediamine.

Among these, from the viewpoint of the thermal conductivity, the amine curing agent is preferably at least one selected from the group consisting of 4,4′-diaminodiphenylemethane, 1,5-diaminonaphthalene and 4,4′-diaminodiphenylsulfone, more preferably 1,5-diaminonaphthalene.

From the viewpoint of reducing the storage elastic modulus while maintaining the thermal conductivity in a cured state, the curing agent preferably includes at least one selected from the group consisting of a compound having a biphenylaralkyl structure (hereinafter, also referred to as a biphenylaralkyl curing agent) and a phenol resin having an allyl group that is directly bonded to a carbon atom in an aromatic ring, or having an alkyl group of not less than 4 carbon atoms that is directly bonded to a carbon atom in an aromatic ring (hereinafter, also referred to as an allyl group/long-chain alkyl group-containing phenol curing agent). The compounds are also referred to as a specific curing agent.

(1) Biphenylaralkyl Curing Agent

The biphenylaralkyl curing agent is not particularly limited, as long as it is a compound having a biphenylaralkyl structure and an ability to function as a curing agent.

Examples of the biphenylaralkyl curing agent include a compound obtained by introducing a biphenylaralkyl structure into a phenol compound (biphenylaralkyl phenol curing agent) and a compound obtained by introducing a biphenylaralkyl structure into an aromatic amine compound (biphenylaralkyl amine curing agent).

Examples of the biphenylaralkyl phenol curing agent include a compound having a structural unit represented by the following Formula (3).

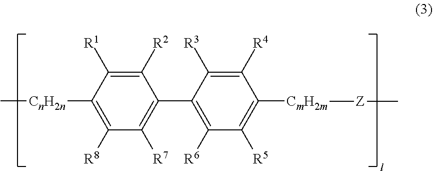

In Formula (1), each of R¹, R², R³, R⁴, R⁵, R⁶, R⁷ and R⁸ independently represents a hydrogen atom or an alkyl group; each of l, m and n independently represents an integer of not less than 1; and each of Z represents a structure represented by the following Formula (4).

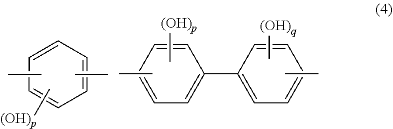

In Formula (4), each of p and q independently represents an integer of from 0 to 2, provided that at least one of Z in Formula (1) has a hydroxy group (i.e., p or q is 1 or 2).

In Formula (1), each of R¹, R², R³, R⁴, R⁵, R⁶, R⁷ and R⁸ independently represents a hydrogen atom or an alkyl group having 1 to 4 carbon atoms, more preferably a hydrogen atom. Each of m and n is preferably independently an integer of from 1 to 4, more preferably 1 or 2, further preferably 1. l is preferably 1 or 2.

In Formula (4), each of p and q is preferably independently 1 or 2, more preferably 1.

The biphenylaralkyl phenol curing agent may be a compound represented by the following Formula (5).

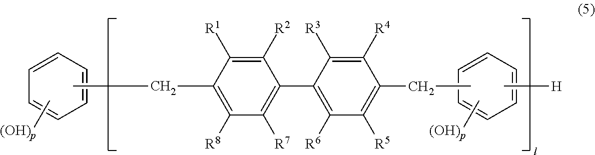

In Formula (5), the definitions of R¹, R², R³, R⁴, R⁵, R⁶, R⁷ and R⁸, and the definitions of l and p are the same as the definitions of R¹, R², R³, R⁴, R⁵, R⁶, R⁷ and R⁸, and the definitions of l and p in Formula (3) and Formula (4).

The weight average molecular weight of the biphenylaralkyl curing agent (Mw) is preferably from 400 to 2000, more preferably from 500 to 1700, further preferably from 800 to 1200.

The number average molecular weight of the biphenylaralkyl curing agent (Mn) is preferably from 200 to 1000, more preferably from 250 to 700, further preferably from 300 to 600.

In the disclosure, the weight average molecular weight and the number average molecular weight of the biphenylaralkyl curing agent are measured by the same manner as the weight average molecular weight and the number average molecular weight of the specific epoxy resin.

When the biphenylaralkyl curing agent is a phenol curing agent, the hydroxy equivalent thereof is preferably from 120 g/eq to 200 g/eq, more preferably from 125 g/eq to 170 g/eq, further preferably from 130 g/eq to 150 g/eq.

In the disclosure, the hydroxy equivalent of the biphenylaralkyl curing agent is measured by the method according to JIS K0070:1992.

When the biphenylaralkyl curing agent is an amine curing agent, the active hydrogen equivalent thereof is preferably from 60 g/eq to 200 g/eq, more preferably from 60 g/eq to 170 g/eq, further preferably from 65 g/eq to 150 g/eq.

In the disclosure, the active hydrogen equivalent of the biphenylaralkyl curing agent is measured by the method according to JIS K7237:1995.

(2) Allyl Group/Long-Chain Alkyl Group-Containing Phenol Curing Agent.

The allyl group/long-chain alkyl group-containing phenol curing agent is a phenol resin having an allyl group that is directly bonded to a carbon atom in an aromatic ring, or a non-cyclic alkyl group of not less than 4 carbon atoms that is directly bonded to a carbon atom in an aromatic ring. This curing agent is in a liquid state at ordinary temperature (25° C.), and is considered to be effective for reducing the elastic modulus of the cured product.

The structure of the phenol resin in the allyl group/long-chain alkyl group-containing phenol curing agent is not particularly limited, but is preferably a novolac obtained from a monofunctional phenol compound. The number of the aromatic ring derived from the phenol compound in the phenol resin is not particularly limited, and is preferably from 2 to 10.

In the allyl group/long-chain alkyl group-containing phenol curing agent, the number of the allyl group or the non-cyclic alkyl group of not less than 4 carbon atoms to be bonded to one aromatic ring is not particularly limited, but is preferably 1 or 2, more preferably 1. The phenol resin may include an aromatic ring to which the allyl group or the non-cyclic alkyl group of not less than 4 carbon atoms is not bonded.

The non-cyclic alkyl group of not less than 4 carbon atoms of the allyl group/long-chain alkyl group-containing phenol curing agent may have a branch or a substituent. In that case, the number of the carbon atoms included in the branch or the substituent is not included in the “carbon atoms” of the non-cyclic alkyl group.

From the viewpoint of achieving a sufficient effect of reducing the storage elastic modulus while maintaining the thermal conductivity, the non-cyclic alkyl group of not less than 4 carbon atoms preferably has no branch or substituent.

The carbon number of the non-cyclic alkyl group of not less than 4 carbon atoms of the allyl group/long-chain alkyl group-containing phenol curing agent is not particularly limited, as long as it is not less than 4. For example, the carbon number may be from 4 to 20.

In the allyl group/long-chain alkyl group-containing phenol curing agent, the bonding site in an aromatic ring for the allyl group or the non-cyclic alkyl group of not less than 4 carbon atoms is not particularly limited. For example, the bonding site may be an ortho position with respect to a hydroxy group bonded to the aromatic ring. When two or more of the allyl group or the non-cyclic alkyl group of not less than 4 carbon atoms are bonded to one aromatic ring, each of them may be at an ortho position or either one of them may be at an ortho position.

The allyl group/long-chain alkyl group-containing phenol curing agent may be a phenol resin having a structural unit represented by the following Formula (6).

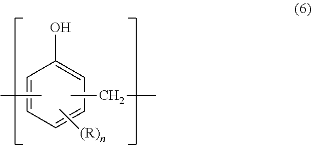

In Formula (6), each of R independently represents an allyl group or a non-cyclic alkyl group of not less than 4 carbon atoms. n is preferably 1 or 2, preferably 1.

In Formula (6), the carbon number of the non-cyclic alkyl group represented by R is not particularly limited as long as it is 4 or more, and may be from 4 to 20, for example.

When the allyl group/long-chain alkyl group-containing phenol curing agent is a phenol resin having a structural unit represented by Formula (6), the number of the structural unit represented by Formula (6) is not particularly limited, but is preferably from 2 to 10 in one molecule. The phenol resin may include an aromatic ring to which an allyl group or a non-cyclic alkyl group of not less than 4 carbon atoms is not bonded.

The bonding site for an allyl group or a non-cyclic alkyl group of not less than 4 carbon atoms in the structural unit represented by Formula (6) is not particularly limited. For example, the bonding site may be an ortho position with respect to a hydroxy group bonded to the aromatic ring. The phenol resin may include an aromatic ring to which an allyl group is bonded and an aromatic ring to which a non-cyclic alkyl group of not less than 4 carbon atoms is bonded, respectively. The phenol resin may include an aromatic ring to which an allyl group and a non-cyclic alkyl group of not less than 4 carbon atoms are bonded.

The weight average molecular weight of the allyl group/long-chain alkyl group-containing curing agent (Mw) is preferably from 200 to 2500, more preferably from 300 to 1800, further preferably from 400 to 1200.

The number average molecular weight of the allyl group/long-chain alkyl group-containing curing agent (Mn) is preferably from 100 to 1300, more preferably from 150 to 800, further preferably from 200 to 400.

In the disclosure, the weight average molecular weight and the number average molecular weight of the allyl group/long-chain alkyl group-containing curing agent are measured by the same manner as the weight average molecular weight and the number average molecular weight of the specific epoxy resin.

The hydroxy equivalent of the allyl group/long-chain alkyl group-containing curing agent is preferably from 100 g/eq to 300 g/eq, more preferably from 110 g/eq to 290 g/eq, further preferably from 120 g/eq to 280 g/eq.

In the disclosure, the hydroxy equivalent of the allyl group/long-chain alkyl group-containing curing agent is measured by the method according to JIS K0070:1992.

When the resin composition includes a specific curing agent, the resin composition may include only a specific curing agent as the curing agent, or may include a specific curing agent and a curing agent that is not a specific curing agent.

When the resin composition includes a specific curing agent and a curing agent that is not a specific curing agent, the proportion of the specific curing agent in the total curing agent is preferably 50% by mass or more, more preferably 70% by mass or more, further preferably 80% by mass or more.

When the resin composition includes a biphenylaralkyl curing agent as the specific curing agent, at least one of a phenol curing agent having a hydroxy equivalent of not more than 120 g/eq or an amine curing agent having an active hydrogen equivalent of not more than 120 g/eq is preferably used in combination with the biphenylaralkyl curing agent. From the viewpoint of storage stability, a phenol curing agent having a hydroxy equivalent of not more than 120 g/eq is more preferably used in combination with the biphenylaralkyl curing agent.

The type of the phenol curing agent having a hydroxy equivalent of not more than 120 g/eq is not particularly limited, and may be selected from the phenol curing agents as described above. Among these, the phenol resin is preferably a novolac resin obtained from a difunctional phenol compound, more preferably a novolac resin obtained from two or more kinds of difunctional phenol compounds, further preferably a catechol-resorcinol novolac resin.

In the disclosure, the hydroxy equivalent of the phenol curing agent is measured by the method according to JIS K0070:1992.

The type of the amine curing agent having an active hydrogen equivalent of not more than 120 g/eq is not particularly limited, and may be selected from the amine curing agent as described above.

In the disclosure, the active hydrogen equivalent of the amine curing agent is measured by the method according to JIS K7237:1995.

(Curing Accelerator)

The resin composition may include a curing accelerator. By using a curing accelerator together with a resin, the resin can be cured more sufficiently. The type or the amount of the curing accelerator is not particularly limited, and may be selected in view of the reaction rate, the reaction temperature and the storability.

Specific examples of the curing accelerator include an imidazol compound, a tertiary amine compound, an organic phosphine compound, and a complex of an organic phosphine compound and an organic boron compound. From the viewpoint of thermal resistance, the curing accelerator is preferably at least one selected the group consisting of an organic phosphine compound and a complex of an organic phosphine compound and an organic boron compound.

Specific examples of the organic phosphine compound include triphenylphosphine, diphenyl(p-tolyl)phosphine, tris(alkylphenyl)phosphine, tris(alkoxyphenyl)phosphine, tris(alkyl.alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylarylphosphine, and alkyldiarylphosphine.

Specific examples of the complex of an organic phosphine compound and an organic boron compound include tetraphenylphosphonium.tetraphenylborate, tetraphenylphoshonium.tetra-p-tolylborate, tetrabutylphosphonium.tetraphenylborate, tetraphenylphosphonium.n-butyltriphenylborate, butyltriphenylphosphonium.tetraphenylborate, and methyltributylphosphonium.tetraphenylborate. The resin composition may include a single kind of the curing accelerator, or may include two or more kinds thereof.

When the resin composition includes a curing accelerator, the content of the curing accelerator in the resin composition is not particularly limited. For example, the content of the curing accelerator is preferably from 0.2% by mass to 3.0% by mass, more preferably from 0.3% by mass to 2.0% by mass, further preferably from 0.4% by mass to 1.5% by mass, with respect to the total mass of the resin.

(Thermally Conductive Filler)

The resin composition may include a thermally conductive filler. The thermally conductive filler may be electrically conductive or not electrically conductive. By using a thermally conductive filler that is not electrically conductive, reduction in the insulating properties tends to be suppressed. Further, by using a thermally conductive filler that is not electrically conductive, thermal conductivity tends to be further improved.

Specific examples of the thermally conductive filler that is not electrically conductive include aluminum oxide (alumina), magnesium oxide, aluminum nitride, boron nitride, silicon nitride, silica (silicon dioxide), silicon oxide, aluminum hydroxide and barium sulfate.

Specific examples of the thermally conductive filler that is electrically conductive include gold, silver, nickel, copper and graphite.

From the viewpoint of the thermal conductivity, the thermally conductive filler is preferably at least one selected from the group consisting of aluminum oxide (alumina), boron nitride, magnesium oxide, aluminum nitride, silica (silicon dioxide) and graphite, more preferably at least one selected from the group consisting of boron nitride and aluminum oxide (alumina). It is possible to use a single kind of the thermally conductive filler or a combination of two or more kinds thereof. For example, it is possible to use aluminum oxide and boron nitride in combination as the thermally conductive filler.

The thermally conductive filler is preferably a mixture of two or more kinds having different volume average particle sizes from each other. In that case, it is possible to achieve a high degree of thermal conductivity by creating a state in which the thermally conductive filler is densely packed by filling spaces among the large particles with the small particles, as compared with a case in which the thermally conductive filler having a uniform size is used.

For example, in a case in which boron nitride and aluminum oxide are used as the thermally conductive filler, it is possible to achieve a high degree of thermal conductivity by combining boron nitride having a volume average particle size of from 20 μm to 100 μm in an amount of from 60% by volume to 95% by volume and aluminum oxide having a volume average particle size of from 0.3 μm to 4 μm in an amount of from 5% by volume to 40% by volume.

The volume average particle size (D50) of the thermally conductive filler may be measured by a laser diffraction scattering method. For example, the particle size of the thermally conductive filler extracted from the resin composition is measured with a laser diffraction scattering particle size analyzer (for example, Beckman Coulter, LS230, trade name). Specifically, a dispersion of the thermally conductive filler is obtained by extracting the same from the resin composition using an organic solvent, nitric acid, aqua regia or the like, and dispersing with an ultrasonic disperser. Then, the volume-based particle size distribution curve is obtained from the dispersion. The particle size at an accumulation of 50% from the side of smaller particle size in the volume-based particle size distribution curve is determined as the volume average particle size (D50).

When the resin composition includes a thermally conductive filler, the content thereof is not particularly limited. From the viewpoint of the thermal conductivity, the content of the thermally conductive filler is preferably greater than 40% by volume, more preferably greater than 50% by volume but not more than 90% by volume, further preferably from 55% by volume to 80% by volume, when the total solid content of the resin composition is regarded as 100% by volume.

When the content of the thermally conductive filler is greater than 50% by volume, it tends to be possible to achieve a higher thermal conductivity. When the content of the thermally conductive filler is not more than 90% by volume, it tends to be possible to suppress the reduction in the flexibility and the insulating properties of a cured product of the resin composition.

When the resin composition includes a thermally conductive filler, the content thereof based on mass is preferably from 30% by mass to 80% by mass, more preferably from 35% by mass to 65% by mass, further preferably from 40% by mass to 60% by mass.

(Silane Coupling Agent)

The resin composition may include at least one kind of a silane coupling agent. The silane coupling agent is considered to have the functions to form a covalent bond between a surface of the thermally conductive filler and a resin around the same (corresponding to a binder), improve the thermal conductivity and inhibit the penetration of moisture, thereby improving the insulation reliability.

The type of the silane coupling agent is not particularly limited, and a commercial product may be used. From the viewpoint of the compatibility with the resin and the curing agent, and the reduction in the thermal conduction defect at an interface between the resin and the thermally conductive filler, a silane coupling agent having an epoxy group, an amino group, a mercapto group, a ureido group or a hydroxy group at a terminal thereof is suitably used.

Specific examples of the silane coupling agent include 3-glycidyloxypropyltrimethoxysilane, 3-glycidyloxypropyltriethoxysilane, 3-glycidyl oxypropylmethyldiethoxysilane, 3-glycidyloxypropylmethyldimethoxysilane, 2-(3,4-epoxycylohexyl)ethyltrimethoxysilane, 3-aminopropyltriethoxysilane, 3-(2-aminoethyl)aminopropyltrimethoxysilane, 3-(2-aminoethyl)aminopropyltriethoxysilane, 3-aminopropyltrimethoxysilane, N-phenyl-3-aminopropyltrimethoxysilane, 3-mercaptopropyltrimethoxysilane, 3-mercaptopropyltriethoxysilane, and 3-ureidopropyltriethoxysilane. It is also possible to use an oligomer-type silane coupling agent, such as SC-6000KS2, Hitachi Chemical Techno Service Co., Ltd.) It is possible to use a single kind of a silane coupling agent, or two or more kinds in combination.

When the resin composition includes a silane coupling agent, the content thereof in the resin composition is not particularly limited. The content of the silane coupling agent is preferably from 0.01% by mass to 0.2% by mass, more preferably from 0.03% by mass to 0.1% by mass, with respect to the total mass of the optionally used epoxy resin and the optionally used curing agent.

(Other Components)

The resin composition may include a component other than the components as described above, and examples thereof include a solvent, an elastomer, a dispersant and an antisetting agent.

<Resin Composition (Second Embodiment)>

The resin composition of the second embodiment is a resin composition, comprising an epoxy resin having a non-cyclic alkylene group of not less than 4 carbon atoms (specific epoxy resin).

The inventors have found that the storage elastic modulus can be reduced while maintaining the thermal conductivity in a cured state, by including a specific epoxy resin in the resin composition. Therefore, it is possible to form a resin member that exhibits excellent connection reliability while maintaining a sufficient degree of thermal conductivity by using the resin composition.

With regard to the details and the preferred embodiments of the resin composition of the second embodiment, the details and the preferred embodiments of the resin composition of the first embodiment may be referred to.

(Use Application of Resin Composition)

The use application of the resin composition is not particularly limited. Since the resin composition according to the disclosure exhibits excellent thermal conductivity and low storage elastic modulus in a cured state, it is suitably used as a material for forming a resin member to be disposed at a portion of an electronic component device that is likely to be exposed to high temperature or is susceptible to warpage. Specific examples of the resin member includes a thermal interface material (TIM), which is used for facilitating the conduction of heat from the device to a heat sink, and a heat dissipation sheet for a power module.

<Resin Member>

The resin member according to the disclosure includes a cured product of the resin composition according to the disclosure.

The use application of the resin member is not particularly limited. Since the resin member exhibits excellent thermal conductivity and a low storage elastic modulus, it is suitably used as a resin member to be disposed at a portion of an electronic component device that is likely to be exposed to high temperature or susceptible to warpage. Specific examples of the resin member includes a thermal interface material (TIM), which is used for facilitating the thermal conduction from the device to a heat sink, and a heat dissipation sheet for a power module.

<Resin Sheet>

The resin sheet according to the disclosure includes the resin composition according to the disclosure.

The density of the resin sheet is not particularly limited, and may be from 3.0 g/cm² to 3.4 g/cm². From the viewpoint of the balance between the flexibility and the thermal conductivity of the resin sheet, the density is preferably from 3.0 g/cm² to 3.3 g/cm², more preferably from 3.1 g/cm² to 3.3 g/cm².

The density of the resin sheet can be adjusted by, for example, the amount of the thermally conductive filler in the resin composition.

The thickness of the resin sheet is not particularly limited, and may be selected depending on the purposes. For example, the thickness of the resin sheet may be from 10 μm to 350 μm. From the viewpoint of the thermal conductivity, insulating properties and flexibility, the thickness of the resin sheet is preferably from 50 μm to 300 μm. The thickness of the resin sheet may be measured by a known method. When the thickness of the resin sheet is not uniform, the arithmetic average value of the thicknesses measured at 5 points is regarded as the thickness of the resin sheet.

The method for producing the resin sheet according to the disclosure is not particularly limited. For example, the resin sheet may be produced by a method including forming, on a support, a layer of the resin composition by applying a varnish of the resin composition prepared by adding an organic solvent such as methyl ethyl ketone or cyclohexanone (hereinafter, also referred to as a resin varnish) with a dispenser or the like, and then removing at least a portion of the organic solvent from the layer by drying the same.

The method for the drying is not particularly limited, as long as at least a portion of the organic solvent included in the resin varnish can be removed, and may be selected from ordinary methods depending on the type, amount or the like of the organic solvent included in the resin varnish.

The resin sheet is in a state with substantially no curing reaction. Therefore, the resin sheet may not be soft enough while having a sufficient degree of flexibility. As a result, the resin sheet may be difficult to handle without a support such as a PET film. Therefore, the resin sheet is preferably subjected to a thermal treatment to allow the resin composition become a semi-cured state.

In the disclosure, a resin sheet obtained by drying the resin composition is also referred to as an A-stage sheet. A resin sheet that is in a semi-cured state, which is obtained by subjecting an A-stage sheet to a thermal treatment, is also referred to as a B-stage sheet. A resin sheet that is in a cured state, which is obtained by subjecting an A-stage sheet or a B-stage sheet to a thermal treatment, is also referred to as a C-stage sheet. The definition of the A-stage, B-stage and C-stage rely on the definitions according to JIS K6900:1994.

<B-Stage Sheet>

The B-stage sheet according to the disclosure include a semi-cured product of the resin sheet according to the disclosure.

The B-stage sheet may be produced by, for example, a method including a process of subjecting the resin sheet to a thermal treatment. By subjecting the resin sheet to a thermal treatment, it is possible to obtain a B-stage sheet that exhibits excellent thermal conductivity and excellent insulating properties, and also exhibits excellent flexibility and excellent pot life.

The semi-cured product of the resin sheet refers to a state in which the resin sheet has a viscosity of from 10⁴ Pa·s to 10⁵ Pa·s at ordinary temperature (25° C.), and a viscosity of from 10² Pa·s to 10³ Pa·s at 100° C. The viscosity is measured by dynamic viscoelasticity measurement (frequency: 1 Hz, load: 40 g, rate of temperature elevation: 3° C./min).

The conditions for the thermal treatment is not particularly limited, as long as it is possible to allow the resin composition to be in a semi-cured state, and may be selected depending on the configuration of the resin composition. From the viewpoint of reducing the voids in the resin sheet, which are formed during the application of the resin varnish, the thermal treatment is preferably performed by a method selected from thermal vacuum pressing, thermal roll laminating, and the like. In that case, it is possible to produce a B-stage sheet having a smooth surface efficiently.

Specifically, for example, a B-stage sheet can be obtained by applying heat and pressure to the resin composition under reduced pressure (such as 1 MPa) at a temperature of from 50° C. to 180° C., a pressing time of from 1 second to 3 minutes, and a pressure of from 1 MPa to 30 MPa.

The thickness of the B-stage sheet may be selected depending on the purposes. For example, the thickness of the B-stage sheet may be from 10 μm to 350 μm. From the viewpoint of the thermal conductivity, insulating properties and flexibility, the thickness of the B-stage sheet is preferably from 50 μm to 300 μm. It is also possible to obtain a B-stage sheet by performing thermal pressing to a laminate of plural resin sheets.

<C-Stage Sheet>

The C-stage sheet according to the disclosure includes a cured product of the resin sheet according to the disclosure.

The C-stage sheet may be produced by a method including a process of subjecting an A-stage sheet or a B-stage sheet to a thermal treatment.

The conditions for the thermal treatment are not particularly limited, as long as the A-stage sheet or the B-stage sheet can be in a cured state, and may be selected depending on the configuration of the resin composition. From the viewpoint of suppressing the formation of the voids and improving the voltage resistance of the C-stage sheet, the thermal treatment is preferably performed by thermal vacuum pressing and the like. In that case, it is possible to produce a C-stage sheet having a smooth surface efficiently.

Specifically, for example, a C-stage sheet can be obtained by applying heat and pressure to the A-stage sheet or the B-stage sheet at a temperature of from 100° C. to 250° C., a pressing time of from 1 minute to 30 minutes, and a pressure of from 1 MPa to 20 MPa. The temperature is preferably from 130° C. to 230° C., more preferably from 150° C. to 220° C.

The thickness of the C-stage sheet may be selected depending on the purposes. For example, the thickness of the C-stage sheet may be from 10 μm to 350 μm. From the viewpoint of the thermal conductivity, insulating properties and flexibility, the thickness of the C-stage sheet is preferably from 50 μm to 300 μm. It is also possible to obtain a C-stage sheet by subjecting a laminate of plural resin sheets or B-stage sheets to thermal pressing.

<Metal Foil with Resin>

The metal foil with resin according to the disclosure includes a metal foil and a semi-cured product of the resin sheet according to the disclosure, which is disposed on the metal foil.

The metal foil with resin exhibits excellent thermal conductivity by having a semi-cured product of the resin sheet according to the disclosure. The semi-cured product of the resin sheet may be obtained by subjecting a resin sheet that is in a state of an A-stage sheet, to a thermal treatment until the resin sheet becomes a B-stage sheet.

The metal foil is not particularly limited, and examples thereof include a gold foil, a copper foil and an aluminum foil, and a copper foil is generally used.

The thickness of the metal foil may be, for example, from 1 μm to 35 μm. From the viewpoint of flexibility, the thickness of the metal foil is preferably 20 μm or less.

The metal foil may be a composite foil having a triple-layered structure or a composite foil having a double-layered structure.

Examples of the triple-layered structure include a structure having an intermediate layer formed from nickel, nickel-phosphor alloy, nickel-tin alloy, nickel-iron alloy, lead, lead-tin alloy or the like, and a copper layer provided on each side of the intermediate layer.

Examples of the double-layered structure include a structure in which an aluminum foil and a copper foil are combined.

In a case of the triple-layered structure having an intermediate layer and copper layers provided on each side of the intermediate layer, it is preferred to adjust the thickness of each of the copper layers to be from 0.5 μm to 15 μm and from 10 μm to 300 μm, respectively.

The metal foil with resin may be produced by, for example, forming a resin sheet by applying a resin composition (preferably a resin varnish) onto a metal foil and drying the same, and subjecting the resin sheet to a thermal treatment until the resin sheet becomes a B-stage sheet. The method for obtaining a resin sheet is as described above.

The conditions for producing the metal foil with resin is not particularly limited. The conditions are preferably adjusted such that at least 80% by mass of an organic solvent included in the resin varnish is removed by drying. The temperature for the drying is not particularly limited, and is preferably from 80° C. to 180° C. The time for the drying may be selected depending on the gelation time of the resin varnish. The amount of the resin varnish to be applied is preferably adjusted such that the thickness of the resin sheet after drying is from 50 μm to 350 μm, more preferably from 60 μm to 300 μm.

The resin sheet after drying becomes a B-stage sheet by subjecting the same to a further thermal treatment. The conditions for the thermal treatment may be the same as the conditions for the thermal treatment for producing a B-stage sheet.

<Metal Substrate>

The metal substrate according to the disclosure has a metal support, a cured product of the resin sheet according to the disclosure, which is disposed on the metal support, and a metal foil that is disposed on the cured product.

By having a cured product of the resin sheet according to the disclosure, the metal support according to the disclosure exhibits excellent thermal conductivity.

The material, thickness and the like of the metal support may be selected as appropriate. Specifically, the metal support may be formed from a metal such as aluminum or iron, and may have a thickness of from 0.5 mm to 5 mm.

The metal foil described in the metal substrate may be the metal foil as described in connection with the metal foil with resin, and preferred embodiments are also the same.

The metal substrate according to the disclosure may be produced by the following method, for example.

A resin sheet is formed on a metal support by applying a resin composition and drying the same, disposing a metal foil on the resin sheet, and curing the resin sheet by applying heat and pressure thereto.

The method for applying and drying the resin composition onto the metal support may be performed by the same method as described in connection with the metal foil with resin. It is also possible to produce a metal substrate by attaching a metal foil with resin to a metal support, such that the semi-cured product of the resin sheet faces the metal support, and drying the semi-cured product of the resin sheet by applying heat and pressure thereto.

<Power Semiconductor Device>

The power semiconductor device according to the disclosure has a semiconductor module in which a metal plate, a solder layer and a semiconductor chip are layered in this order; a heat dissipation member; and a cured product of the resin sheet according to the disclosure, which is disposed between the metal plate of the semiconductor module and the heat dissipation member.

The power semiconductor device may have only a semiconductor module portion sealed with a sealing material or the like, or may have the entire body of the power semiconductor device molded with a molding resin and the like. In the following, an example of a configuration of the power semiconductor device is described by referring to the drawings.

FIG. 1 is a schematic sectional view showing an exemplary configuration of the power semiconductor device. In FIG. 1, metal plate 106, solder layer 110 and semiconductor chip 108 are disposed in this order to form a semiconductor module. A cured product of resin sheet 102 is disposed between metal plate 106 and heat-dissipation base substrate 104, and a portion corresponding to the semiconductor module is sealed with sealing material 114.

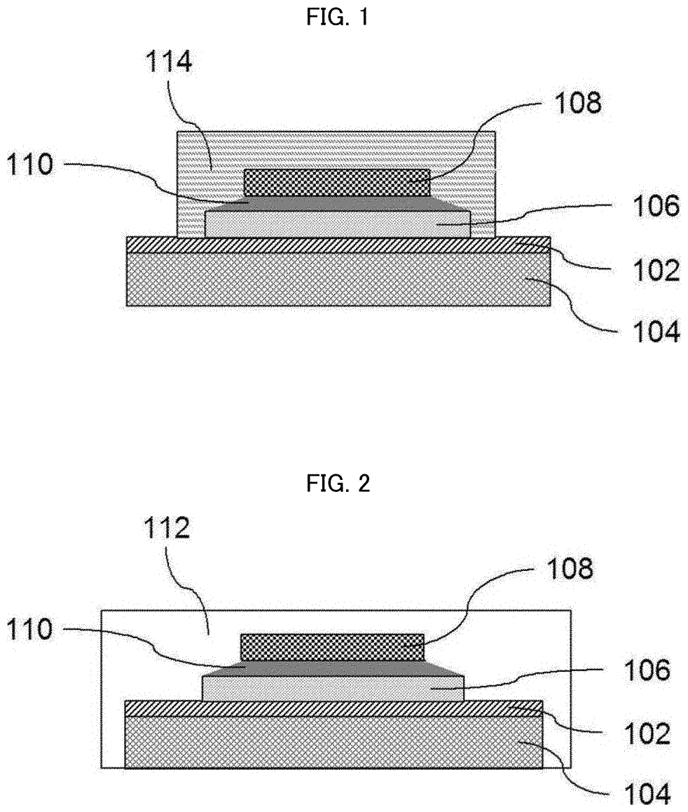

FIG. 2 is a schematic sectional view showing another exemplary configuration of the power semiconductor device. In FIG. 2, metal plate 106, solder layer 110 and semiconductor chip 108 are disposed in this order to form a semiconductor module. A cured product of resin sheet 102 is disposed between metal plate 106 and heat-dissipation base substrate 104, and the semiconductor module and heat-dissipation base substrate 104 are molded with molding resin 112.

As mentioned above, a cured product of the resin sheet according to the disclosure can be used as an adhesive layer having a heat-dissipation ability, as shown in FIG. 1. Further, a cured product of the resin sheet according to the disclosure can be used as a heat-dissipation member between the heat-dissipation base substrate and the metal plate, even in the case of molding the entire body of the power semiconductor device, as shown in FIG. 2.

### EXAMPLES

In the following, the invention is described in further details by referring to the Examples. However, the invention is not limited to these Examples. The following are the materials and the abbreviation thereof used for preparing the resin composition.

(Epoxy Resin)

Epoxy resin 1: YL6121H (biphenyl epoxy monomer, Mitsubishi Chemical Corporation, Epoxy equivalent: 172 g/eq)

Epoxy resin 2: 4-{4-(2,3-epoxypropoxy)phenyl}cyclohexyl=4-(2,3-epoxypropoxy)benzoate, epoxy equivalent: 212 g/eq, having the following structure, prepared in the method described in Japanese Patent Application Laid-Open No. 2011-74366)

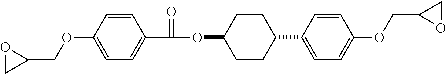

Epoxy resin 3: epoxy resin represented by Formula (1) in which m is 6 (n=1 to 20, epoxy equivalent: 1124 g/eq)

Epoxy resin 4: epoxy resin represented by Formula (2) in which m is 4 (n=1 to 20, epoxy equivalent: 440 g/eq)

Curing agent 1: biphenylaralkyl curing agent (MEHC-7403H, Meiwa Plastic Industries, Ltd., hydroxy equivalent: 136 g/eq)

Curing agent 2: catechol-resorcinol novolac resin (CRN) synthesized by the following method

Curing agent 3: phenol novolac resin having an allyl group directly bonded to a carbon atom in an aromatic ring (MEH8000S, Meiwa Plastic Industries, Ltd., hydroxy equivalent: 140 g/eq)

Curing agent 4: phenol novolac resin having an alkyl group of not less than 4 carbon atoms directly bonded to a carbon atom in an aromatic ring (ELPC80S, Gun Ei chemical Industry Co., Ltd., hydroxy equivalent: 213 g/eq)

(Method for Synthesis of CRN)

To a 3 L separable flask having a stirrer, a cooler and a thermometer, resorcinol (627 g), catechol (33 g) and an aqueous solution of formaldehyde in 37% by mass (316.2 g), oxalic acid (15 g) and water (300 g) were added, and the temperature was elevated to 100° C. with an oil bath. The mixture was refluxed at approximately 104° C. and the reaction was continued for 4 hours at the reflux temperature. Thereafter, the temperature inside the flask was elevated to 170° C. while distilling away the water. The reaction was continued for 8 hours while maintaining the temperature at 170° C. After the reaction, the reactant was concentrated under reduced pressure for 20 minutes, and the water or the like was removed, thereby obtaining a catechol-resorcinol novolac resin (CRN) (the mass ratio at the preparation: catechol/resorcinol=5/95, containing 50% by mass of cyclohexanone).

The CRN included 35% by mass of unreacted monomer component (resorcinol) and had the hydroxy equivalent of 62 g/eq, the number average molecular weight of 422, and the weight average molecular weight of 564.

(Thermally Conductive Filler)

AA-04 (alumina particles, Sumitomo Chemical Co., Ltd., D50: 0.4 μm)

HP-40 (boron nitride particles, Mizushima Ferroalloy Co., Ltd., D50: 40 μm)

(Curing Accelerator)

Curing accelerator 1: triphenylphosphine (Fujifilm Wako Pure Chemical Corporation)

Curing accelerator 2: trialkylphosphine-hydroquinone adduct

(Silane Coupling Agent)

KBM-573: N-phenyl-3-aminopropyltrimethoxysilane (Shin-Etsu Chemical Co., Ltd., trade name)

(Solvent)

CHN: cyclohexanone

(Support)

PET film (Teijin Film Solutions Limited, trade name: A53, thickness: 50 μm)

Copper foil (Furukawa Electric Co., Ltd., thickness: 105 μm, GTS grade)

### Comparative Example 1

A resin composition in the form of a varnish was prepared by mixing epoxy resin 1 (2.12% by mass), epoxy resin 2 (10.72% by mass), curing agent 1 (2.60% by mass), curing agent 2 (5.19% by mass), curing accelerator 1 as a curing accelerator (0.14% by mass), HP-40 as a thermally conducive filler (39.39% by mass), KBM-573 as an additive (0.04% by mass) and CHN as a solvent (34.94% by mass).

The proportion of the thermally conductive filler with respect to the total volume of the total solid content of the resin composition was calculated under the condition that the densities of boron nitride (HP-40), alumina (AA-04) and the resin (mixture of epoxy resin and curing agent) were 2.20 g/cm³, 3.98 g/cm³ and 1.20 g/cm³, respectively. The result was 56% by volume.

(Preparation of C-Stage Sheet for Evaluation)

The resin composition was applied onto a roughened surface of a copper foil with a dispenser (Musashi Engineering, Inc., SHOTMASTER 300DS-S, trade name) such that the size and the thickness of the resin sheet after drying was 50 mm×50 mm and 200 μm, respectively. The resin composition was dried in an oven (ESPEC Corporation, SPHH-201, trade name) at ordinary temperature (20° C. to 30° C.) for 5 minutes and further at 130° C. for 5 minutes.

Subsequently, the resin sheet was subjected to hot pressing under vacuum (pressing temperature: 150° C., degree of vacuum: 1 kPa, pressure: 10 MPa, pressing time: 1 minute) with a polyethylene terephthalate (PET) film disposed thereon, thereby obtaining a B-stage resin sheet with a copper foil.

Subsequently, the PET film was removed from the B-stage resin sheet with a copper foil, and a resin sheet with a copper foil obtained by the same manner was disposed thereon such that the resin sheets face each other. In this state, the resin sheets were subjected to hot pressing under vacuum (pressing temperature: 150° C., degree of vacuum: 1 kPa, pressure: 10 MPa, pressing time: 30 minutes). Thereafter, the resin sheets were heated at 150° C. for 2 hours and at 210° C. for 4 hours, thereby obtaining a C-stage resin sheet with copper foils.

(Measurement of Thermal Conductivity)

The copper foils were removed by etching, thereby obtaining a C-stage sheet. A sample with a size of 10 mm×10 mm was obtained from the C-stage sheet. The sample was subjected to a blackening treatment with a graphite spray, and the thermal diffusivity was evaluated by a xenon flash method (NETSCH, LFA447 NanoFlash, trade name). From the product of the measured thermal diffusivity, the density measured by Archimedes method, and the specific heat measured by differential scanning calorimetry (DSC) with an analyzer (Parkin Elmer, DSC Pyrisl, trade name), the thermal conductivity of the C-stage sheet in a thickness direction was calculated. The result is shown in Table 1.

(Measurement of Storage Elastic Modulus)

The copper foils were removed by etching, thereby a C-stage sheet. A sample with a size of 30 mm×5 mm was obtained from the C-stage sheet. The sample was subjected to a tensile test using a dynamic viscoelasticity measurement device (TA Instruments, RSA II) under a frequency of 10 Hz, a rate of temperature elevation of 5° C./min, and a temperature range of from 25° C. to 300° C., and the elastic modulus (storage elastic modulus) at 30° C. was measured. The result is shown in Table 1.

(Evaluation of Connection Reliability)

A simplified package for evaluating the connection reliability was prepared using a substrate on which a semiconductor chip was mounted (Hitachi Chemicals Corporation, MCL-E-700G(R), 0.81 mm), an underfill material (Hitachi Chemicals Corporation, CEL-C-3730N-2), and a silicone adhesive as a sealing material (Dow Toray Co., Ltd., SE4450). Further, a copper plate having a nickel-plated surface with a thickness of 1 mm was used as a heat spreader. The size of the heat spreader and the size of the semiconductor were 45 mm and 20 mm, respectively.

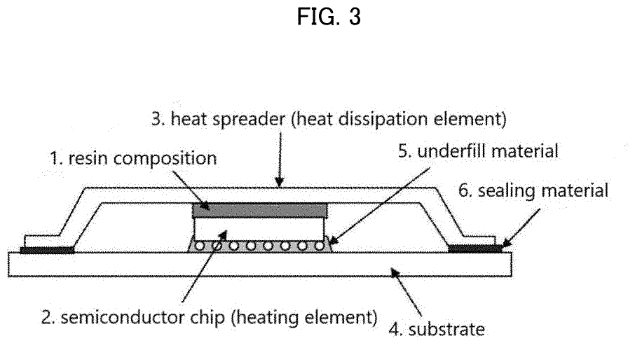

The resin composition prepared in the Examples and the Comparative Examples was applied onto the heat spreader with a dispenser (Musashi Engineering, Inc., SHOTMASTER 300DS-S, trade name) to form a resin composition layer having a size of 30 mm×30 mm and a thickness of 200 μm. The heat spreader with a resin composition layer was subjected to heat pressing using a high-accuracy press-heat bonding machine (Alpha-Design Co., Ltd., HTB-MM) with a hot plate temperature at 150° C. and a pressure of 1 MPa for 3 minutes. Thereafter, the sealing material and the resin composition were thoroughly cured by a curing treatment in a thermostat chamber at 150° C. for 2 hours, thereby obtaining a simplified package having a configuration as shown in FIG. 3. The simplified package was subjected to a reflow test (260° C., 300 seconds, three times).

The simplified package after the reflow test was observed with an ultrasonic image analyzer (Insight K.K., Insight-300) by a reflection method at 35 MHz. The obtained image was binarized with an image analysis soft (ImageJ), and the proportion of the adhesion area (%) with respect to the area corresponding to the semiconductor chip (20 mm×20 mm) was calculated. The adhesion area is determined as the total of the area at which the cured product of the resin composition is in contact with the heat spreader and the area at which the cured product of the resin composition is in contact with the chip. The result were evaluated according to the following criteria.

OK: the adhesion area after the reflow test was 95% or more

NG: the adhesion area after the reflow test was less than 95%

### Comparative Example 2

(Preparation of Resin Composition)

A resin composition in the form of a varnish was prepared by mixing epoxy resin 1 (3.39% by mass), epoxy resin 2 (17.13% by mass), curing agent 1 (2.36% by mass), curing agent 2 (10.61% by mass), curing accelerator 1 as a curing accelerator (0.26% by mass), HP-40 as a thermally conducive filler (36.97% by mass), AA-04 as a thermally conducive filler (4.57% by mass), KBM-573 as an additive (0.04% by mass) and CHN as a solvent (24.67% by mass).

The proportion of the thermally conductive filler with respect to the total volume of the total solid content of the resin composition was calculated under the condition that the densities of boron nitride (HP-40), alumina (AA-04) and the resin (mixture of epoxy resin and curing agent) were 2.20 g/cm³, 3.98 g/cm³ and 1.20 g/cm³, respectively. The result was 40% by volume.

(Evaluation)

A C-stage sheet was prepared, and the thermal conductivity and the storage elastic modulus were measured in the same manner as Comparative Example 1, except that the pressing was performed at 1 MPa. Further, a package was prepared and the connection reliability was evaluated in the same manner as Comparative Example 1. The results are shown in Table 1.

### Example 1

(Preparation of Resin Composition)

A resin composition in the form of a varnish was prepared by mixing epoxy resin 3 (17.14% by mass), curing agent 1 (0.37% by mass), curing agent 2 (1.67% by mass), curing accelerator 1 as a curing accelerator (0.15% by mass), HP-40 as a thermally conducive filler (41.48% by mass), AA-04 as a thermally conducive filler (5.13% by mass), KBM-573 as an additive (0.05% by mass) and CHN as a solvent (34.01% by mass).

The proportion of the thermally conductive filler with respect to the total volume of the total solid content of the resin composition was calculated under the condition that the densities of boron nitride (HP-40), alumina (AA-04) and the resin (mixture of epoxy resin and curing agent) were 2.20 g/cm³, 3.98 g/cm³ and 1.20 g/cm³, respectively. The result was 56% by volume.

(Evaluation)

A C-stage sheet was prepared, and the thermal conductivity and the storage elastic modulus were measured in the same manner as Comparative Example 1, except that the pressing was performed at 1 MPa. Further, a package was prepared and the connection reliability was evaluated in the same manner as Comparative Example 1. The results are shown in Table 1.

### Example 2

(Preparation of Resin Composition)

A resin composition in the form of a varnish was prepared by mixing epoxy resin 3 (17.61% by mass), curing agent 3 (2.13% by mass), curing accelerator 1 as a curing accelerator (0.16% by mass), HP-40 as a thermally conducive filler (43.12% by mass), AA-04 as a thermally conducive filler (5.33% by mass), KBM-573 as an additive (0.05% by mass) and CHN as a solvent (31.59% by mass).

The proportion of the thermally conductive filler with respect to the total volume of the total solid content of the resin composition was calculated under the condition that the densities of boron nitride (HP-40), alumina (AA-04) and the resin (mixture of epoxy resin and curing agent) were 2.20 g/cm³, 3.98 g/cm³ and 1.20 g/cm³, respectively. The result was 56% by volume.

(Evaluation)

A C-stage sheet was prepared, and the thermal conductivity and the storage elastic modulus were measured in the same manner as Comparative Example 1, except that the pressing was performed at 1 MPa. Further, a package was prepared and the connection reliability was evaluated in the same manner as Comparative Example 1. The results are shown in Table 1.

### Example 3

(Preparation of Resin Composition)

A resin composition in the form of a varnish was prepared by mixing epoxy resin 3 (16.60% by mass), curing agent 4 (3.15% by mass), curing accelerator 1 as a curing accelerator (0.16% by mass), HP-40 as a thermally conducive filler (43.12% by mass), AA-04 as a thermally conducive filler (5.33% by mass), KBM-573 as an additive (0.05% by mass) and CHN as a solvent (31.59% by mass).

The proportion of the thermally conductive filler with respect to the total volume of the total solid content of the resin composition was calculated under the condition that the densities of boron nitride (HP-40), alumina (AA-04) and the resin (mixture of epoxy resin and curing agent) were 2.20 g/cm³, 3.98 g/cm³ and 1.20 g/cm³, respectively. The result was 56% by volume.

(Evaluation)

A C-stage sheet was prepared, and the thermal conductivity and the storage elastic modulus were measured in the same manner as Comparative Example 1, except that the pressing was performed at 1 MPa. Further, a package was prepared and the connection reliability was evaluated in the same manner as Comparative Example 1. The results are shown in Table 1.

### Example 4

(Preparation of Resin Composition)

A resin composition in the form of a varnish was prepared by mixing epoxy resin 4 (14.88% by mass), curing agent 1 (0.82% by mass), curing agent 2 (3.70% by mass), curing accelerator 2 as a curing accelerator (0.15% by mass), HP-40 as a thermally conducive filler (41.48% by mass), AA-04 as a thermally conducive filler (5.13% by mass), KBM-573 as an additive (0.05% by mass) and CHN as a solvent (33.79% by mass).

The proportion of the thermally conductive filler with respect to the total volume of the total solid content of the resin composition was calculated under the condition that the densities of boron nitride (HP-40), alumina (AA-04) and the resin (mixture of epoxy resin and curing agent) were 2.20 g/cm³, 3.98 g/cm³ and 1.20 g/cm³, respectively. The result was 56% by volume.

(Evaluation)

A C-stage sheet was prepared, and the thermal conductivity and the storage elastic modulus were measured in the same manner as Comparative Example 1, except that the pressing was performed at 1 MPa. Further, a package was prepared and the connection reliability was evaluated in the same manner as Comparative Example 1. The results are shown in Table 1.

### Example 5

(Preparation of Resin Composition)

A resin composition in the form of a varnish was prepared by mixing epoxy resin 4 (14.98% by mass), curing agent 3 (4.77% by mass), curing accelerator 2 as a curing accelerator (0.16% by mass), HP-40 as a thermally conducive filler (43.12% by mass), AA-04 as a thermally conducive filler (5.33% by mass), KBM-573 as an additive (0.05% by mass) and CHN as a solvent (31.59% by mass).

The proportion of the thermally conductive filler with respect to the total volume of the total solid content of the resin composition was calculated under the condition that the densities of boron nitride (HP-40), alumina (AA-04) and the resin (mixture of epoxy resin and curing agent) were 2.20 g/cm³, 3.98 g/cm³ and 1.20 g/cm³, respectively. The result was 56% by volume.

(Evaluation)

A C-stage sheet was prepared, and the thermal conductivity and the storage elastic modulus were measured in the same manner as Comparative Example 1, except that the pressing was performed at 1 MPa. Further, a package was prepared and the connection reliability was evaluated in the same manner as Comparative Example 1. The results are shown in Table 1.

### Example 6

(Preparation of Resin Composition)

A resin composition in the form of a varnish was prepared by mixing epoxy resin 4 (13.30% by mass), curing agent 4 (6.44% by mass), curing accelerator 2 as a curing accelerator (0.16% by mass), HP-40 as a thermally conducive filler (43.12% by mass), AA-04 as a thermally conducive filler (5.33% by mass), KBM-573 as an additive (0.05% by mass) and CHN as a solvent (31.60% by mass).

The proportion of the thermally conductive filler with respect to the total volume of the total solid content of the resin composition was calculated under the condition that the densities of boron nitride (HP-40), alumina (AA-04) and the resin (mixture of epoxy resin and curing agent) were 2.20 g/cm³, 3.98 g/cm³ and 1.20 g/cm³, respectively. The result was 56% by volume.

(Evaluation)

A C-stage sheet was prepared, and the thermal conductivity and the storage elastic modulus were measured in the same manner as Comparative Example 1, except that the pressing was performed at 1 MPa. Further, a package was prepared and the connection reliability was evaluated in the same manner as Comparative Example 1. The results are shown in Table 1.

TABLE 1

| | Comparative | | | | | | | |
|---|---|---|---|---|---|---|---|---|
| | Example | | Example | | | | | |
| | 1 | 2 | 1 | 2 | 3 | 4 | 5 | 6 |
| Thermal | 10 | 3 | 8 | 8 | 8 | 9 | 9 | 9 |
| conductivity | | | | | | | | |
| [W/(m · K)] | | | | | | | | |
| Storage elastic | 10 | 6 | 2 | 1 | 1 | 0.8 | 0.5 | 0.2 |
| modulus [Gpa] | | | | | | | | |
| Connection | NG | OK | OK | OK | OK | OK | OK | OK |
| reliability | | | | | | | | |

As shown in Table 1, a cured product prepared from the resin composition of Comparative Example 1, in which an epoxy resin having a mesogenic structure was used, had a sufficient degree of thermal conductivity but the storage elastic modulus was too high and the connection reliability was not satisfactory.

Comparative Example 2, in which the amount of the filler was less than Comparative Example 1, had a lower storage elastic modulus and the connection reliability was satisfactory, but the thermal conductivity was insufficient.

A cured product prepared from the resin composition of each of Examples 1 to 6, in which an epoxy resin having a non-cyclic alkylene group of not less than 4 carbon atoms was used, had a sufficient degree of thermal conductivity and the connection reliability was satisfactory.

All publications, patent applications, and technical standards mentioned in the present specification are incorporated herein by reference to the same extent as if each individual publication, patent application, or technical standard was specifically and individually indicated to be incorporated by reference.

### EXPLANATION OF SYMBOLS

102: cured product of resin sheet, 104: heat-dissipation substrate, 106: metal plate, 108: semiconductor chip, 110: solder layer, 112: molding resin, 114: sealing material

1. A resin composition having, in a cured state, a thermal conductivity of 5 W/(m·K) or more and a storage elastic modulus of 8 GPa or less.

2. The resin composition according to claim 1, comprising a thermosetting resin.

3. The resin composition according to claim 1, comprising an epoxy resin having a non-cyclic alkylene group of not less than 4 carbon atoms.

4. The resin composition according to claim 1, comprising a phenol resin having an allyl group that is directly bonded to a carbon atom in an aromatic ring, or having an alkyl group of not less than 4 carbon atoms that is directly bonded to a carbon atom in an aromatic ring.

5. A resin composition, comprising an epoxy resin having a non-cyclic alkylene group of not less than 4 carbon atoms.

6. A resin member, comprising a cured product of the resin composition according to claim 1.

7. A resin sheet, comprising the resin composition according to claim 1.

8. A B-stage sheet, comprising a semi-cured product of the resin sheet according to claim 7.

9. A C-stage sheet, comprising a cured product of the resin sheet according to claim 7.

10. A metal foil with resin, comprising a metal foil and a semi-cured product of the resin sheet according to claim 7, which is disposed on the metal foil.

11. A metal substrate, comprising a metal support, a cured product of the resin sheet according to claim 7, which is disposed on the metal support, and a metal foil that is disposed on the cured product.

12. A power semiconductor device, comprising a semiconductor module in which a metal plate, a solder layer and a semiconductor chip are layered in this order; a heat dissipation member; and a cured product of the resin sheet according to claim 7, which is disposed between the metal plate of the semiconductor module and the heat dissipation member.
